(19) United States
(12) Patent Application Publication
(10) Pub. No.: US 2011/0156259 A1
(43) Pub. Date: Jun. 30, 2011

(54) METAL-TO-CONTACT OVERLAY STRUCTURES AND METHODS OF MANUFACTURING THE SAME

(75) Inventor: Chin Cheng Yang, Gangshan Town (TW)

(73) Assignee: Macronix International Co., Ltd., Hsin-chu (TW)

(21) Appl. No.: 12/763,549

(22) Filed: Apr. 20, 2010

(30) Foreign Application Priority Data
Dec. 29, 2009 (TW) 098145652

(51) Int. Cl. H01L 23/532

(52) U.S. Cl. 257/762; 257/E23.161

(57) ABSTRACT

The present invention provides a semiconductor device with a metal-to-contact overlay structure. The semiconductor device includes a substrate, a dielectric layer on the substrate, a contact coupled to the substrate in the dielectric layer, a first conductive region on the contact in the dielectric layer, a dielectric sidewall on the contact in the dielectric layer, the dielectric sidewall surrounding the first conductive region, and a second conductive region on the first conductive region on the dielectric layer.

### BACKGROUND OF THE INVENTION

The present invention generally relates to semiconductor memory devices. More particularly, the present invention relates to metal-to-contact (ML-to-CO) overlay structures in a semiconductor memory device and methods of manufacturing a semiconductor memory device with the ML-to-CO overlay structure.

To reduce the die size of each single chip for manufacturing more chips with a single wafer, miniaturization is an important design direction to shrink the size of each semiconductor device to save chip areas in modern semiconductor industry. However, as the size becomes smaller, semiconductor process for manufacturing such semiconductor devices may face more challenges.

FIG. 1A is a diagram illustrating an exemplary metal-to-contact (ML-to-CO) overlay structure in prior art. Referring to FIG. 1A, the ML-to-CO overlay structure may include a number of contacts 11 in a dielectric layer 12 on a substrate 10, and a number of metals 13 each on one of the contacts 11. Ideally, in a semiconductor process, each metal 13 is required to be formed exactly on its corresponding contact 11. However, due to the trend of miniaturization, devices or components and the spacing therebetween in a semiconductor product are shrunk as the semiconductor product is downsized. As a result, more strict design rules such as the limitations on line widths or spaces between two wires have been adopted and hence more precise alignment is required for the manufacturing of semiconductor products.

FIG. 1B is a diagram illustrating an issue with the ML-to-CO overlay structure shown in FIG. 1A. Referring to FIG. 1B, the contacts 11 and metals 13 may be offset with respect to each other because of, for example, manufacture inaccuracy or deviation during manufacturing processes. Consequently, undesired short-circuiting (shown in a dashed circle) may occur, which may destroy the semiconductor product.

It may therefore be desirable to have a reliable ML-to-CO overlay structure and a method of manufacturing the same that is able to alleviate the inaccuracy or deviation issue.

### BRIEF SUMMARY OF THE INVENTION

Examples of the present invention may provide a semiconductor device with a metal-to-contact overlay structure. The semiconductor device includes a substrate, a dielectric layer on the substrate, a contact coupled to the substrate in the dielectric layer, a first conductive region on the contact in the dielectric layer, a dielectric sidewall on the contact in the dielectric layer, the dielectric sidewall surrounding the first conductive region, and a second conductive region on the first conductive region on the dielectric layer.

Some examples of the present invention may provide a semiconductor device with a metal-to-contact overlay structure. The semiconductor device includes a substrate, a dielectric layer on the substrate, a first contact coupled to the substrate in the dielectric layer, a second contact coupled to the substrate in the dielectric layer, a first conductive region on each of the first and second contacts in the dielectric layer, a dielectric sidewall on each of the first and second contacts in the dielectric layer, the dielectric sidewall surrounding the first conductive region, and a second conductive region on the first conductive region on the dielectric layer.

Examples of the present invention may also provide a semiconductor device with a metal-to-contact overlay structure. The semiconductor device includes a substrate, a dielectric layer on the substrate, a contact through the dielectric layer to the substrate, a dielectric sidewall surrounding an upper portion of the contact in the dielectric layer, and a conductive region on the upper portion of the contact on the dielectric layer.

Examples of the present invention may provide a method of forming a metal-to-contact overlay structure in a semiconductor device. The method comprises providing a substrate, forming a first dielectric layer on the substrate, forming a number of conductive plugs through the first dielectric layer to the substrate, etching back the conductive plugs, resulting in a number of contacts and a number of recesses defined by the contacts and the first dielectric layer, wherein each of the recesses includes a sidewall that is portion of the first dielectric layer, forming a second dielectric layer on the first dielectric layer and the contacts, patterning the second dielectric layer, resulting in a patterned second dielectric layer on the sidewall of each of the recesses, forming a conductive layer on the first dielectric layer and the patterned second dielectric layer, the conductive layer filling the recesses, resulting in a number of first conductive regions, and patterning the conductive layer, resulting in a number of second conductive regions each on one of the first conductive regions.

Examples of the present invention may also provide a method of forming a metal-to-contact overlay structure in a semiconductor device. The method comprises providing a substrate, forming a first dielectric layer on the substrate, forming a number of openings through the first dielectric layer, exposing portions of the substrate, forming a conductive layer on the first dielectric layer, the conductive layer filling the openings, resulting in a number of conductive plugs, etching back the conductive plugs, resulting in a number of contacts and a number of recesses defined by the contacts and the first dielectric layer, wherein each of the recesses includes a sidewall that is portion of the first dielectric layer, forming a second dielectric layer on the first dielectric layer and the contacts, patterning the second dielectric layer, resulting in a patterned second dielectric layer on the sidewall of each of the recesses, forming a second conductive layer on the first dielectric layer and the patterned second dielectric layer, the second conductive layer filling the recesses, resulting in a number of first conductive regions, removing the second conductive layer on the first dielectric layer, exposing the first dielectric layer, the patterned second dielectric layer and the first conductive regions, forming a third conductive layer on the first dielectric layer, the patterned second dielectric layer and the first conductive regions, and patterning the third conductive layer, resulting in a number of second conductive regions each on one of the first conductive regions.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings examples which are presently preferred. It should be understood, however, that the invention is not limited to the precise arrangements and instrumentalities shown.

In the drawings:

FIG. 1A is a diagram of an exemplary metal-to-contact (ML-to-CO) overlay structure in prior art;

FIG. 1B is a diagram illustrating an issue with the ML-to-CO overlay structure shown in FIG. 1A;

FIGS. 2A to 2H are diagrams schematically illustrating cross-sectional views of a method of forming a metal-to-contact (ML-to-CO) overlay structure according to an example of the present invention; and

FIGS. 3A to 3D are diagrams schematically illustrating cross-sectional views of a method of forming an ML-to-CO overlay structure according to another example of the present invention.

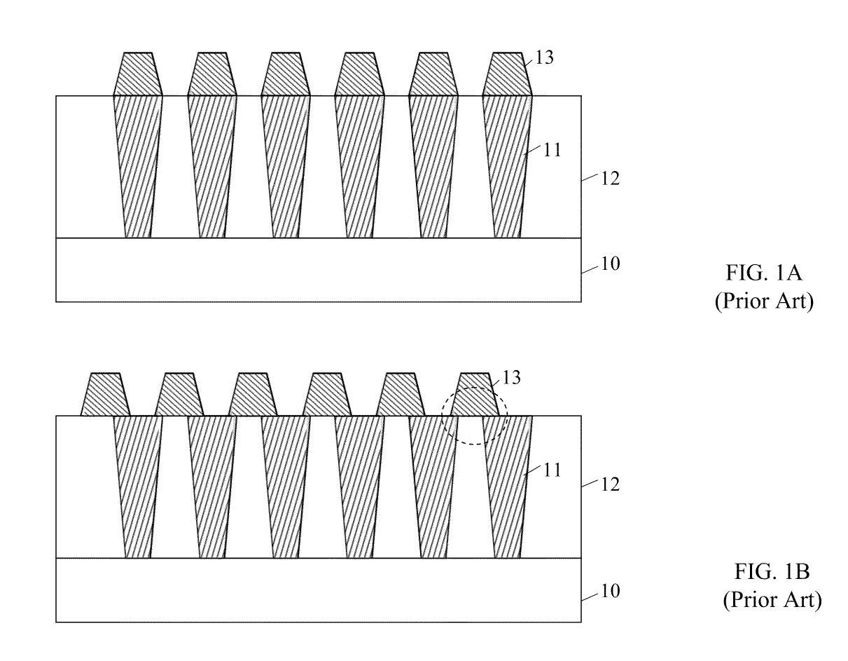

### DETAILED DESCRIPTION OF THE INVENTION

Reference will now be made in detail to the present examples of the invention, examples of which are illustrated in the accompanying drawings. Wherever possible, the same reference numbers will be used throughout the drawings to refer to the same or like parts.

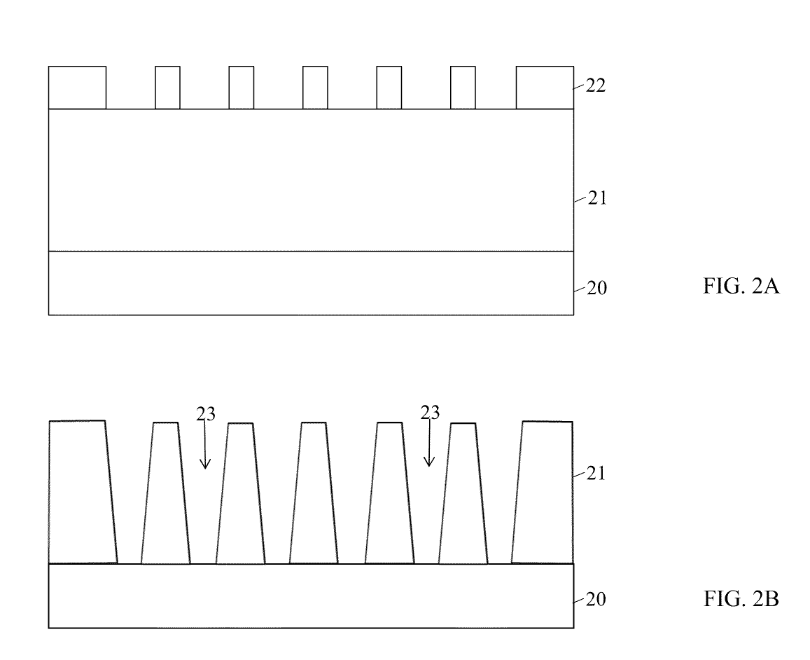

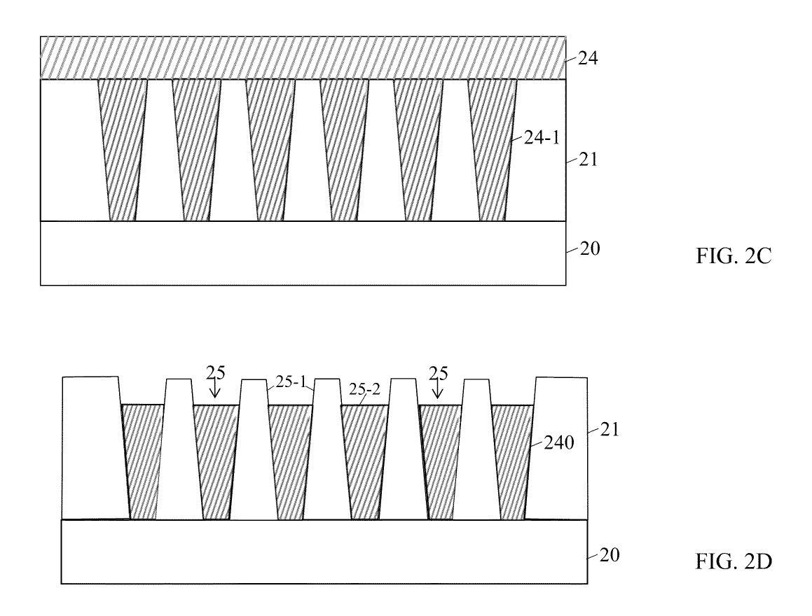

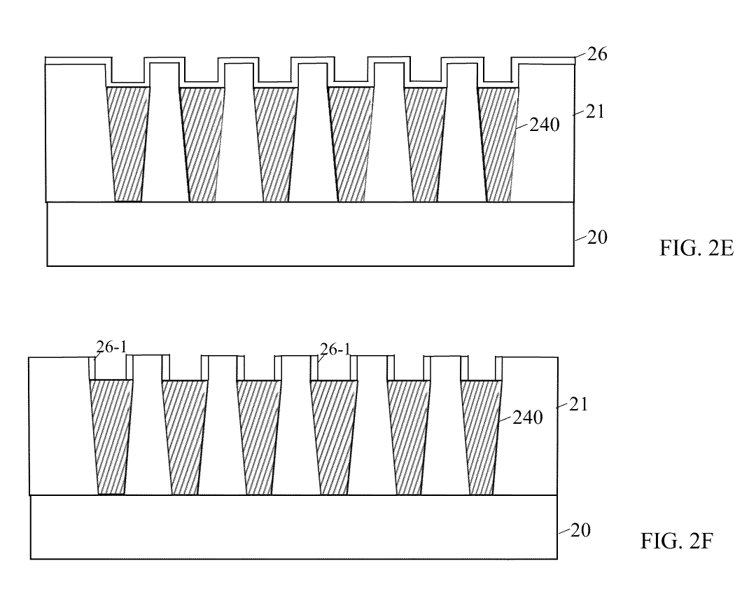

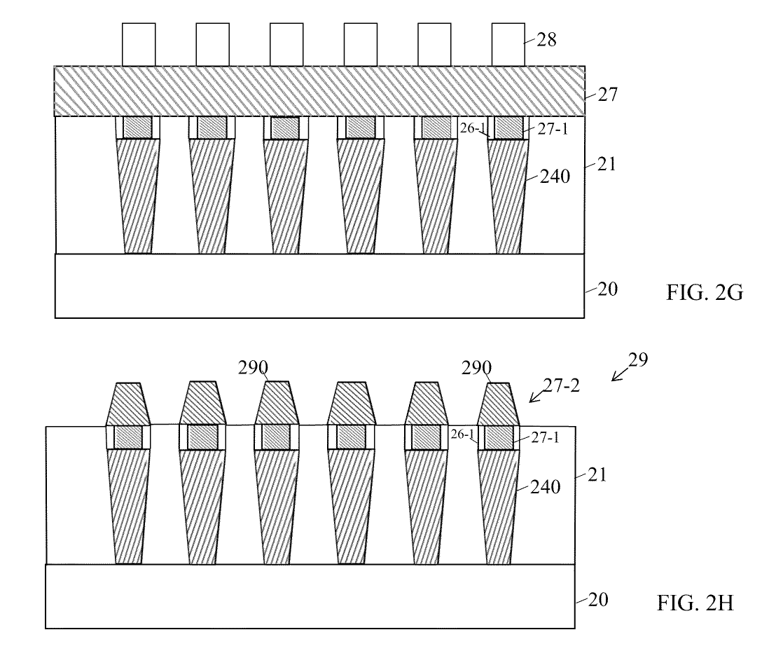

FIGS. 2A to 2H are diagrams schematically illustrating cross-sectional views of a method of forming a metal-to-contact (ML-to-CO) overlay structure according to an example of the present invention. In the examples of the present invention, the “metal” may refer to a conductive layer or one or more conductive line over a substrate of a semiconductor memory device, while the “contact” may refer to a conductive via, plug or path to electrically couple a conductive region, for example, a diffused region such as a source/drain region in the substrate, to the metal in the semiconductor memory device. Skilled persons in the art will understand that the methods and overlay structures according to the present invention may be applicable to semiconductor devices wherever the ML-to-CO overlay issue may concern.

Referring to FIG. 2A, a silicon (Si) substrate 20, which may have been doped with a p-type impurity, is provided. An array of memory cells (not shown), including transistors such as bipolar or p-type/n-type metal-oxide-semiconductor field effect transistors (MOSFETs), may be formed on the substrate 20. A first dielectric layer 21 may be formed on the memory array and the substrate 20 by a deposition process. In one example, the first dielectric layer 21 may include silicon oxide. Next, a first patterned photoresist layer 22 may be formed on the first dielectric layer 21 by a coating process followed by a photolithography process, exposing portions of the first dielectric layer 21.

Referring to FIG. 2B, a number of openings 23 may be formed in the first dielectric layer 21 through the exposed portions of the first dielectric layer 21 to the substrate 20 by an etching process, using the first patterned photoresist layer 22 as a mask. In the present example, a dry etch process may be used, resulting in the openings 23 each having a profile tapered from the exposed portion to the substrate 20. The first patterned photoresist layer 22 may then be stripped.

Referring to FIG. 2C, a first conductive layer 24 may be formed on the first dielectric layer 21 by a deposition process, for example, a chemical vapor deposition (CVD) process. The first conductive layer 24 fills the openings 23 during the deposition process, resulting in a number of conductive plugs 24-1 in the first dielectric layer 21. In one example, the first conductive layer 24 may include but is not limited to tungsten (W).

Referring to FIG. 2D, the conductive plugs 24-1 may be partially removed by an etch-back process. Specifically, by controlling the etch time, the first conductive layer 24 formed on the first dielectric layer 21 may be etched off and the conductive plugs 24-1 may be etched back, resulting in contacts 240 with a reduced height from the surface of the first dielectric layer 21. A number of recesses 25 may be defined by the first dielectric layer 21 and the contacts 240. Each of the recesses 25 may include a sidewall 25-1 that is an upper portion of the first dielectric layer 21, and a bottom surface 25-2 that is the top surface of a corresponding one of the contacts 240.

Referring to FIG. 2E, a second dielectric layer 26 may be formed on the first dielectric layer 21 and the recesses 25 by a deposition process. In one example, the second dielectric layer 26 may include silicon oxide, silicon nitride or silicon oxynitride, which may have a substantially uniform thickness on the first dielectric layer 21, and the sidewalls 25-1 and bottom surfaces 25-2 of the recesses 25.

Referring to FIG. 2F, the second dielectric layer 26 may be removed by an etch process except the portions thereof on the sidewalls 25-1 of the recesses 25, resulting in a patterned second dielectric layer 26-1. That is, the portions of the second dielectric layer 26 on the first dielectric layer 21 and the bottom surfaces 25-2 of the recesses 25 are etched off during the etch process. The patterned second dielectric layer 26-1 may function to provide electric isolation between the contacts 240 and metals to be subsequently formed on the contacts 240 when, if any, offset of the contacts 240 relative to the metals may occur.

Referring to FIG. 2G, a second conductive layer 27 may be formed on the first dielectric layer 21 and the patterned second dielectric layer 26-1 by a deposition process. The second conductive layer 27 fills the recesses 25 during the deposition process, resulting in a number of first conductive regions 27-1. In one example according to the present invention, the second conductive layer 27 may include bit is not limited to one of aluminum (Al), copper (Cu) and an alloy of Al and Cu. Next, a second patterned photoresist layer 28, which may mask the first conductive regions 27-1, may be formed on the second conductive layer 27.

Referring to FIG. 2H, the second conductive layer 27 may be partially removed by an etch process, using the patterned second photoresist layer 28 as a mask, resulting in a number of second conductive regions 27-2 each on one of the first conductive regions 27-1. Furthermore, each of the second conductive regions 27-2 may serve as a metal line for the ML-to-CO overlay structure. Accordingly, an ML-to-CO overlay structure 29 including a number of overlay units 290 is formed. Each of the overlay units 290 includes the contact 240 of a first conductive material in the first dielectric layer 21, the first conductive region 27-1 of a second conductive material on the contact 240, the dielectric sidewall 26-1 surrounding the first conductive region 27-1, and the second conductive region 27-2 of the second conductive material on the first conductive region 27-1.

In one example, the contact 240 may include a first or bottom surface (not numbered) in contact with a diffused region in the substrate 20, and a second or top surface (not numbered) within the first dielectric layer 21. Furthermore, the first conductive region 27-1 is disposed on the second surface of the contact 240 and substantially coplanar with the first dielectric layer 21. Moreover, the dielectric sidewall 26-1 surrounding the first conductive region 27-1 is disposed on the second surface of the contact 240 and substantially coplanar with the first dielectric layer 21. In the present example, the second conductive region 27-2 is disposed on the dielectric sidewall 26-1. The overlay structure 29 may alleviate the short-circuiting issue in that the dielectric sidewall 26-1 provides electric isolation when the second conductive region 27-2 is, due to process factor, offset from the first conductive region 27-1. In that case, the second conductive region 27-2 may overlap one of the dielectric sidewall 26-1 of an immediately adjacent overlay unit 290. In one example, the dielectric sidewall 26-1 has a width of approximately 10 nanometers (nm), which may provide an additional amount of isolation against short-circuiting due to significant offset between the first conductive regions 27-1 and the overlay units 290.

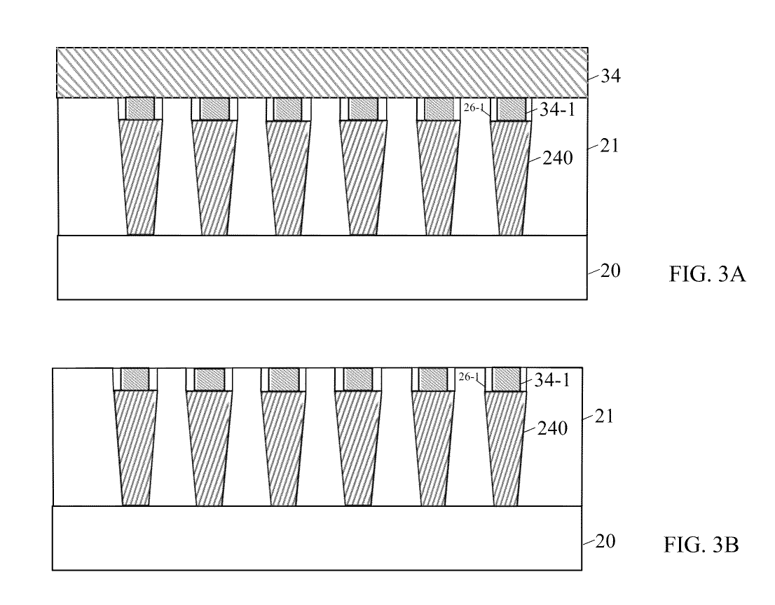

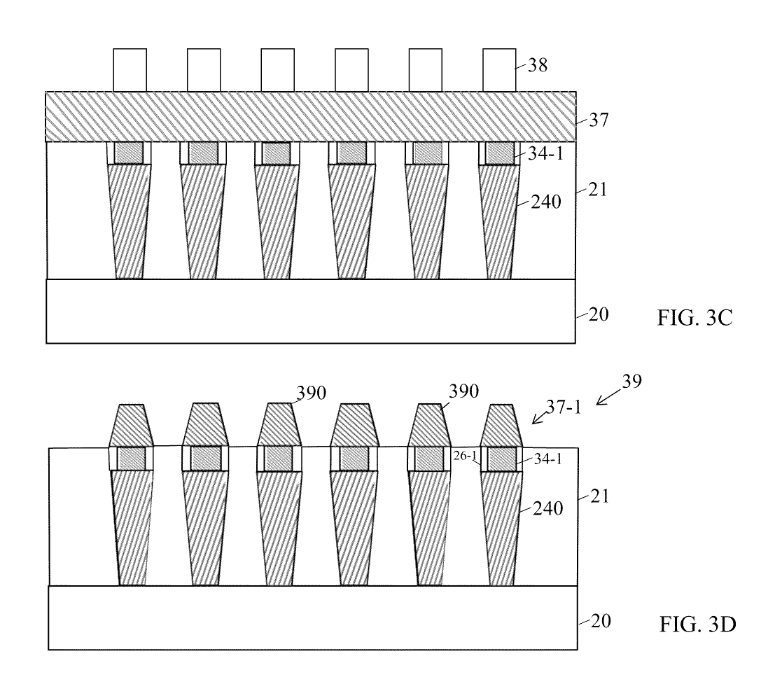

FIGS. 3A to 3D are diagrams schematically illustrating cross-sectional views of a method of forming an ML-to-CO overlay structure according to another example of the present invention. Turning back to FIG. 2F, after the patterned second dielectric layer 26-1 is formed, now referring to FIG. 3A, a second conductive layer 34 of the same material as the first conductive layer 24 may be formed on the first dielectric layer 21 and the patterned second dielectric layer 26-1 by a deposition process. The second conductive layer 34 fills the recesses 25 during the deposition process, resulting in a number of first conductive regions 34-1.

Referring to FIG. 3B, the second conductive layer 34 on the first dielectric layer 21 may be removed by, for example, a chemical mechanical polish (CMP) process, exposing the first dielectric layer 21, the first conductive regions 34-1 and the patterned second dielectric layer 26-1.

Referring to FIG. 3C, a third conductive layer 37 may be formed on the first dielectric layer 21, the first conductive regions 34-1 and the patterned second dielectric layer 26-1 by a deposition process. In one example according to the present invention, the third conductive layer 37 may include bit is not limited to one of aluminum (Al), copper (Cu) and an alloy of Al and Cu. Next, a second patterned photoresist layer 38, which may mask the first conductive regions 34-1, may be formed on the third conductive layer 37.

Referring to FIG. 3D, the third conductive layer 37 may be partially removed by an etch process, using the patterned second photoresist layer 38 as a mask, resulting in a number of second conductive regions 37-1 each on one of the first conductive regions 34-1. Furthermore, each of the second conductive regions 37-1 may serve as a metal line for the ML-to-CO overlay structure. Accordingly, an ML-to-CO overlay structure 39 including a number of overlay units 390 is formed. Each of the overlay units 390 includes the contact 240 of a first conductive material in the first dielectric layer 21, the first conductive region 34-1 of the first conductive material on the contact 240, the dielectric sidewall 26-1 surrounding the first conductive region 34-1, and the second conductive region 37-1 of a second conductive material on the first conductive region 34-1.

It will be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims. Further, in describing representative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A semiconductor device with a metal-to-contact overlay structure, the semiconductor device comprising:
a substrate;
a dielectric layer on the substrate;
a contact coupled to the substrate in the dielectric layer;
a first conductive region on the contact in the dielectric layer;
a dielectric sidewall on the contact in the dielectric layer, the dielectric sidewall surrounding the first conductive region; and
a second conductive region on the first conductive region on the dielectric layer.

2. The semiconductor device of claim 1, wherein the contact includes a first conducive material, and the first conductive region and second conductive region include a second conductive material, which is different from the first conductive material.

3. The semiconductor device of claim 1, wherein the contact and the first conductive region include a first conducive material, and the second conductive region includes a second conductive material, which is different from the first conductive material.

4. The semiconductor device of claim 1, wherein the contact includes tungsten (W), and the first conductive region and second conductive region include one of aluminum (Al), copper (Cu) and an alloy of Al and Cu.

5. The semiconductor device of claim 1, wherein the contact and the first conductive region includes tungsten (W), and the second conductive region includes one of aluminum (Al), copper (Cu) and an alloy of Al and Cu.

6. The semiconductor device of claim 1, wherein the contact is coupled to a diffused region in the substrate.

7. The semiconductor device of claim 1, wherein the first conductive region is coplanar with the dielectric layer.

8. The semiconductor device of claim 1, wherein the dielectric sidewall is coplanar with the dielectric layer.

9. A semiconductor device with a metal-to-contact overlay structure, the semiconductor device comprising:
a substrate;
a dielectric layer on the substrate;
a first contact coupled to the substrate in the dielectric layer;
a second contact coupled to the substrate in the dielectric layer;
a first conductive region on each of the first and second contacts in the dielectric layer;
a dielectric sidewall on each of the first and second contacts in the dielectric layer, the dielectric sidewall surrounding the first conductive region; and
a second conductive region on the first conductive region on the dielectric layer.

10. The semiconductor device of claim 9, wherein the first and second contacts include a first conducive material, and the first conductive region and second conductive region include a second conductive material, which is different from the first conductive material.

11. The semiconductor device of claim 9, wherein the first and second contacts and the first conductive region include a first conducive material, and the second conductive region includes a second conductive material, which is different from the first conductive material.

12. The semiconductor device of claim 9, wherein the first and second contacts include tungsten (W), and the first conductive region and the second conductive region include one of aluminum (Al), copper (Cu) and an alloy of Al and Cu.

13. The semiconductor device of claim 9, wherein the first and second contacts and the first conductive region include tungsten (W), and the second conductive region includes one of aluminum (Al), copper (Cu) and an alloy of Al and Cu.

14. The semiconductor device of claim 9, wherein the second conductive region of the first contact is disposed on the first conductive region and the dielectric sidewall on the first contact.

15. The semiconductor device of claim 9, wherein the second conductive region of the first contact overlaps the dielectric sidewall on the second contact.

16. The semiconductor device of claim 9, wherein the first conductive region is coplanar with the dielectric layer.

17. The semiconductor device of claim 9, wherein the dielectric sidewall is coplanar with the dielectric layer.

18. A semiconductor device with a metal-to-contact overlay structure, the semiconductor device comprising:
a substrate;
a dielectric layer on the substrate;
a contact through the dielectric layer to the substrate;
a dielectric sidewall surrounding an upper portion of the contact in the dielectric layer; and
a conductive region on the upper portion of the contact on the dielectric layer.

19. The semiconductor device of claim 18, wherein the contact includes a first conducive material, and the conductive region includes a second conductive material, which is different from the first conductive material.

20. The semiconductor device of claim 18, wherein the contact includes tungsten (W), and the conductive region includes one of aluminum (Al), copper (Cu) and an alloy of Al and Cu.
